(19) United States
(12) Patent Application Publication
(10) Pub. No.: US 2025/0309158 A1
(43) Pub. Date: Oct. 2, 2025

(54) ELECTRONIC DEVICES

(71) Applicant: InnoLux Corporation, Miao-Li County (TW)

(72) Inventors: Jui-Jen YUEH, Miao-Li County (TW); Ju-Li WANG, Miao-Li County (TW); Yen-Fu LIU, Miao-Li County (TW)

(21) Appl. No.: 19/063,618

(22) Filed: Feb. 26, 2025

(30) Foreign Application Priority Data
Mar. 26, 2024 (CN) 202410349409.8

(51) Int. Cl. H01L 23/00

(52) U.S. Cl. CPC H01L 24/02; H01L 2224/02331; H01L 2224/02379; H01L 2224/024

(57) ABSTRACT

An electronic device is provided. The electronic device includes an electronic element; a conductive pad disposed on the electronic element and electrically connected to the electronic element; and a redistribution structure disposed on the conductive pad. The redistribution structure includes a plurality of conductive layers; a polymer layer enclosing the conductive layers; and a bump electrically connected to the conductive pad through the conductive layers. The center of the conductive pad is horizontally shifted from the center of the bump. The conductive layers include a first conductive layer. The first conductive layer has a side surface contacting the polymer layer, and the side surface has a side edge having roughness of 0.08 μm to 0.8 μm in a cross-sectional view.

### CROSS-REFERENCE TO RELATED APPLICATIONS

The present application claims priority of China Application No. 202410349409.8, filed on March, 26, 2024, which is incorporated by reference herein in its entirety.

### BACKGROUND

### Technical Field

The present disclosure is related to an electronic device, and more particularly it is related to a packaging technology for an electronic device.

### Description of the Related Art

Fan-out packaging, such as fan-out wafer level package (FOWLP) or fan-out panel level package (FOPLP) technology, can increase the integration density of electronic components (for example, transistors, diodes, resistors, capacitors, etc.) in a given area. It has been widely used in production and manufacturing of electronic devices in recent years.

However, a fan-out packaging structure has many interface integration structures of heterogeneous materials (for example, an interface between a redistribution layer (RDL) and a conductive pad, etc.), and the interface between heterogeneous materials is prone to problems such as delamination or peeling due to the presence of large amounts of stress.

Therefore, improvement of the reliability of the packaging structure of an electronic device is still one of the current research topics in the industry.

### SUMMARY

Some embodiments of the present disclosure provide an electronic device. The electronic device includes an electronic element; a conductive pad disposed on the electronic element and electrically connected to the electronic element; and a redistribution structure disposed on the conductive pad. The redistribution structure includes a plurality of conductive layers; a polymer layer enclosing the conductive layers; and a bump electrically connected to the conductive pad through the conductive layers. The center of the conductive pad is horizontally shifted from the center of the bump. The conductive layers include a first conductive layer. The first conductive layer has a side surface contacting the polymer layer, and the side surface has a side edge having roughness of 0.08 μm to 0.8 μm in a cross-sectional view.

### BRIEF DESCRIPTION OF THE DRAWINGS

Embodiments of the present disclosure can be best understood from the following detailed description in conjunction with the accompanying drawings. It should be noted that, in accordance with the common practice in the industry, various features are not drawn to scale. In fact, the dimensions of the various elements may be arbitrarily increased or reduced to clearly illustrate the features of the embodiments of the present disclosure. It should also be noted that the drawings illustrate typical embodiments of the present disclosure. The drawings should not be considered as limitation of the present disclosure. The present disclosure may also be applied to other embodiments.

FIGS. 1-5 illustrate schematic cross-sectional views of an electronic device at different manufacturing stages, according to some embodiments of the present disclosure.

FIG. 6 illustrates an enlarged view of a partial area of the electronic device of FIG. 5, according to some embodiments of the present disclosure.

FIGS. 7 and 8 illustrate schematic cross-sectional views of the electronic device at different manufacturing stages, according to some embodiments of the present disclosure.

FIG. 9 illustrates an enlarged view of a partial area of the electronic device of FIG. 8, according to some embodiments of the present disclosure.

FIGS. 10-12 illustrate schematic cross-sectional views of the electronic device at different manufacturing stages, according to some embodiments of the present disclosure.

FIG. 13 illustrates an enlarged view of a partial area of the electronic device of FIG. 12, according to some embodiments of the present disclosure.

### DETAILED DESCRIPTION

The following disclosure provides many different embodiments, or examples, for implementing different features of the described subject matter. Specific examples of elements and arrangements are described below to simplify the present description. These are, of course, merely examples and are not intended to be limiting. For example, a formation of a first feature over or on a second feature in the description that follows may include embodiments in which the first and second features are formed in direct contact, and may also include embodiments in which additional features may be formed between the first and second features, such that the first and second features may not be in direct contact. Furthermore, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

When an element or layer is “on” or “connected to” another element or layer, it can be directly on or directly connected to another element or layer, or there is an inserted element or layer between the two (indirect case). In contrast, when an element is “directly on” or “directly connected to” another element or layer, there is no intervening element or layer presented. In addition, the term “electrical connection” or “coupling” includes any direct and indirect means of electrical connection.

It should be understood that the ordinal numbers used in the present disclosure, such as the terms “first”, “second”, “third”, etc., are used to modify an element, which itself does not mean and represent that the element (or elements) has any previous ordinal number, and does not mean the order of a certain element and another element, or the order in the manufacturing method. The use of these ordinal numbers is to make an element with a certain name can be clearly distinguished from another element with the same name. The claims and the specification may not use the same terms. For example, the first element in the specification may refer to the second element in the claims.

In the following descriptions, terms “about” and “substantially” typically mean +/−10% of the stated value, or typically +/−5% of the stated value, or typically +/−3% of the stated value, or typically +/−2% of the stated value, or typically +/−1% of the stated value or typically +/−0.5% of the stated value. The expression “in a range from the first value to the second value” or “between the first value and the second value” means that the range includes the first value, the second value, and other values in between. The values given in the present disclosure are approximate. That is, without specifying terms the terms “about” and “substantially”, the meaning of “about” and “substantially” can still be implied.

Some embodiments of the present disclosure are described below. Additional steps or operations may be provided before, during, and/or after the steps or operations described in these embodiments. Some of the steps or operations described may be replaced or deleted in different embodiments. In addition, it should be understood that in the following embodiments, without departing from the spirit of the present disclosure, the features in several different embodiments can be replaced, recombined, and mixed to complete another embodiment. The features between the various embodiments can be mixed and matched arbitrarily as long as they do not violate or conflict the spirit of the present disclosure.

In accordance with the embodiments of the present disclosure, the electronic device may include a power module, a semiconductor packaging device, a display device, a backlight device, an antenna device, a touch device, a sensing device, a wearable device, a vehicle device, a battery device, or a tiled device, but it is not limited thereto. The electronic device may be a bendable or flexible electronic device. The display device may be a non-self-luminous display device or a self-luminous display device. The antenna device may be a liquid-crystal type antenna device or a non-liquid-crystal type antenna device. The sensing device may be a sensing device that senses capacitance, light, heat energy or ultrasonic waves, but it is not limited thereto. Furthermore, the electronic device may include, for example, liquid crystals, quantum dots (QDs), fluorescence, phosphorescence, another suitable material, or a combination thereof. The electronic device may include electronic components. The electronic components may include passive components and active components, such as capacitors, resistors, inductors, diodes, transistors, integrated circuits, etc. The diode may include a light-emitting diode or a photodiode. The light-emitting diode may include, for example, an organic light-emitting diode (OLED), a mini light-emitting diode (mini LED), a micro light-emitting diode (micro LED) or a quantum dot light-emitting diode (quantum LED), but it is not limited thereto. In accordance with some embodiments, the electronic device may include a panel and/or a backlight module. The panel may include, for example, a liquid-crystal panel or another self-luminous panel, but it is not limited thereto. The tiled device may be, for example, a display tiled device or an antenna tiled device, but it is not limited thereto. It should be understood that the electronic device can be any permutation and combination of the above, but it is not limited thereto. In accordance with the embodiments of the present disclosure, the provided method of manufacturing the electronic device can include, for example, a wafer-level package (WLP) or panel-level package (PLP) process, and a chip-first process or a chip-last/RDL first process may be used, which will be explained in further detail below. The electronic device referred to in the present disclosure may include a system on package (SoC), a system in package (SiP), an antenna in package (AiP), or a combination thereof, but it is not limited thereto. In accordance with the embodiments of the present disclosure, the electronic component is exemplified by a die. Furthermore, the die may be a semiconductor die, and the electronic device may be a semiconductor package.

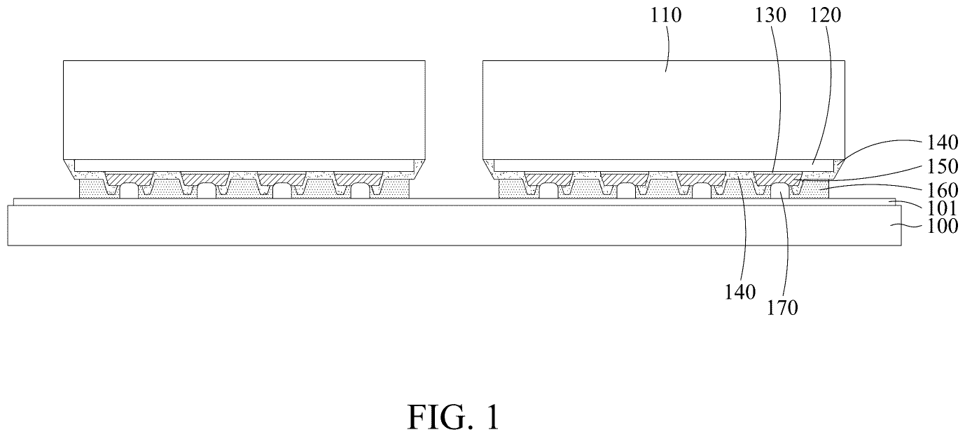

Referring to FIG. 1, an electronic component 110 is disposed on a first substrate 100 through an adhesive layer 101. In some embodiments, the first substrate 100 may include glass, quartz, ceramics, steel plates, silicon wafers, another suitable material, or a combination thereof, but the present disclosure is not limited thereto. In some embodiments, the first substrate 100 may be a glass substrate, such as oxide glass, fluoride glass, oxynitride glass, but the present disclosure is not limited thereto. In other embodiments, the first substrate 100 may be a wafer, but the present disclosure is not limited thereto. In some embodiments, the electronic component 110 may include an integrated circuit die, a surface mount device (SMD), another suitable electronic component, or a combination thereof, but the present disclosure is not limited thereto.

Still referring to FIG. 1, the adhesive layer 101 is disposed on the first substrate 100. The adhesive layer 101 may be detached from an overlying structure with the first substrate 100 in subsequent steps. In some embodiments, the adhesive layer 101 may include polymer-based materials, but the present disclosure is not limited thereto. For example, the adhesive layer 101 may include thermal release tape (HRT) or light-to-heat-conversion (LTHC) coating, which loses adhesion when heated. In other embodiments, the adhesive layer 101 may include ultra-violet (UV) glue, which loses adhesion when exposed to ultra-violet light. In other embodiments, the adhesive layer 101 may lose adhesion through a laser peeling process. In some embodiments, the adhesive layer 101 may be formed through a coating and curing process, a lamination process, another suitable process, or a combination thereof.

Still referring to FIG. 1, a circuit layer 120, a barrier layer 130, a passivation layer 140, a conductive pad 150, a polymer layer 160 and an opening 170 are provided between the electronic component 110 and the adhesive layer 101. In some embodiments, the circuit layer 120 may include copper (Cu), titanium (Ti), tantalum (Ta), tungsten (W), nickel (Ni), molybdenum (Mo), aluminum (Al), silver (Ag), gold (Au), another suitable material, or a combination thereof, but the present disclosure is not limited thereto. In some embodiments, the barrier layer 130 may include titanium (Ti), tantalum (Ta), another suitable material, or a combination thereof, but the present disclosure is not limited thereto.

In some embodiments, the passivation layer 140 may include an inorganic material. For example, the inorganic material may include silicon nitride, silicon oxide, silicon oxynitride, another suitable material, or a combination thereof, but the present disclosure is not limited thereto. In some embodiments, the passivation layer 140 may be formed through a coating process (for example, a spin-coating process), a chemical vapor deposition (CVD) process, a physical vapor deposition (PVD) process, another suitable method, or a combination thereof. The passivation layer 140 can reduce the influence of moisture and oxygen from the external environment on the electronic component 110. In addition, the passivation layer 140 may be patterned through one or more lithography processes and/or etching processes. The lithography process may include photoresist coating (for example, spin-coating), soft baking, hard baking, mask alignment, exposure, post-exposure baking, photoresist development, cleaning and drying, etc., but the present disclosure is not limited thereto. The etching process may include a dry etching process or a wet etching process, but the present disclosure is not limited thereto.

In some embodiments, the conductive pad 150 may include a conductive material, such as aluminum (Al) or another suitable conductive material, but the present disclosure is not limited thereto. In some embodiments, the conductive material may be formed through a physical vapor deposition (PVD) process, an electroplating process, an electroless plating process (also known as a chemical plating process), another suitable method, or a combination thereof. In addition, the conductive pad 150 may be formed by patterning the conductive material through one or more lithography processes and/or etching processes.

In some embodiments, the polymer layer 160 may include a polymer dielectric material, such as polybenzoxazole (PBO), polyimide (PI), benzocyclobutene (BCB), another suitable polymer dielectric material or a combination thereof, but the present disclosure is not limited thereto. In some embodiments, the polymer layer 160 may be formed through a coating process (for example, a spin-coating process), a lamination process, a chemical vapor deposition process, another suitable method, or a combination thereof.

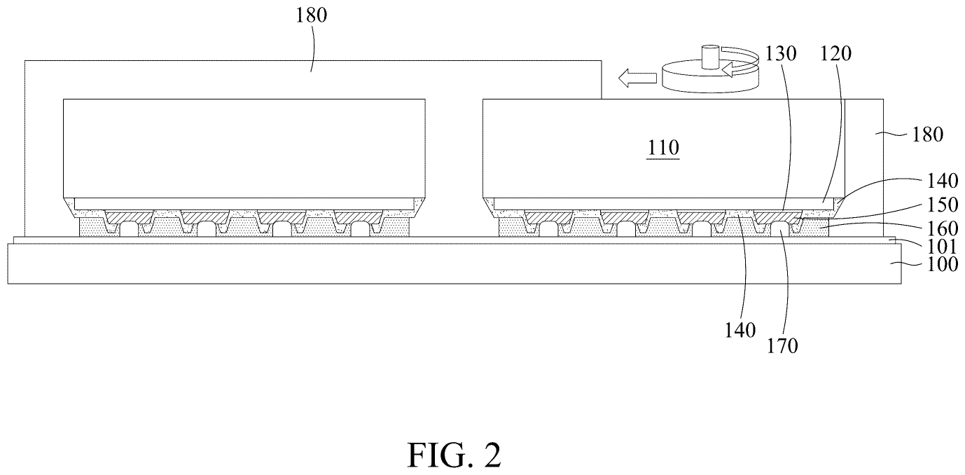

Referring to FIG. 2, a molding layer 180 is formed to seal the electronic component 110. In some embodiments, the molding layer 180 may include molding compound, epoxy, another suitable encapsulating material, or a combination thereof, but the present disclosure is not limited thereto. In some embodiments, the molding layer 180 may be formed through a compression molding process, a transfer molding process, or another suitable method. In some embodiments, the molding layer 180 may be in a liquid or semi-liquid form during the molding process and then be cured. Subsequently, a planarization process, such as chemical mechanical polishing (CMP), may be performed to make the top surface of the molding layer 180 flush with the top surface of the electronic component 110.

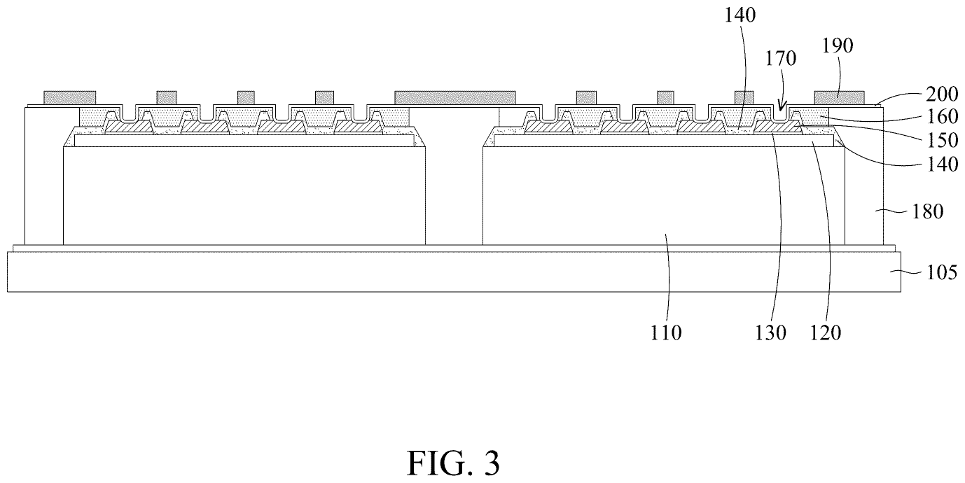

Referring to FIG. 3, after the formation of the molding layer 180, the adhesive layer 101 may lose adhesion, for example, through a thermal process, an ultra-violet light process or a laser process, so that the structure on the adhesive layer 101 is separated from the adhesive layer 101 and the first substrate 100. The structure initially on the adhesive layer 101 is flipped and then disposed on a second substrate 105. The material of the second substrate 105 may be similar to the material of the first substrate 100. In the interests of brevity, the description thereof is not repeated herein.

Still referring to FIG. 3, a first seed layer 200 is formed on the polymer layer 160, on the molding layer 180 and in the opening 170. In some embodiments, the first seed layer 200 may include titanium (Ti), tantalum (Ta), copper (Cu), another suitable material, or a combination thereof, but the present disclosure is not limited thereto. In some embodiments, the first seed layer 200 may be formed through an atomic layer deposition (ALD) process, a physical vapor deposition (PVD) process, an electroplating process, an electroless plating process, another suitable method, or a combination thereof. The physical vapor deposition process may include, for example, a sputtering process and an evaporation process. Subsequently, dry film photoresists 190 may be formed on the first seed layer 200.

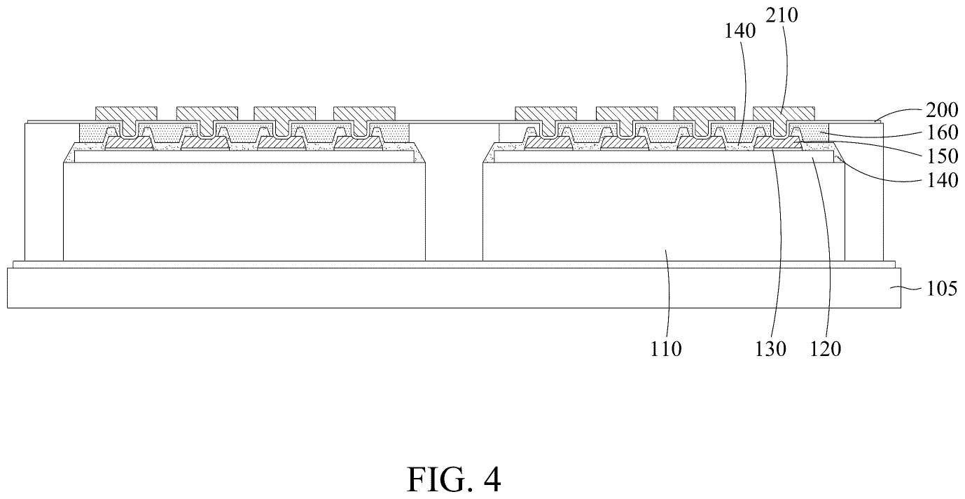

Referring to FIG. 4, a first conductive layer 210 is formed between the dry film photoresists 190. In some embodiments, the first conductive layer 210 may include copper (Cu), nickel (Ni), another suitable conductive material, or a combination thereof, but the present disclosure is not limited thereto. In some embodiments, the first conductive layer 210 may be formed through a physical vapor deposition (PVD) process, an electroplating process, an electroless plating process, another suitable method, or a combination thereof. After the formation of the first conductive layer 210, the dry film photoresists 190 are removed.

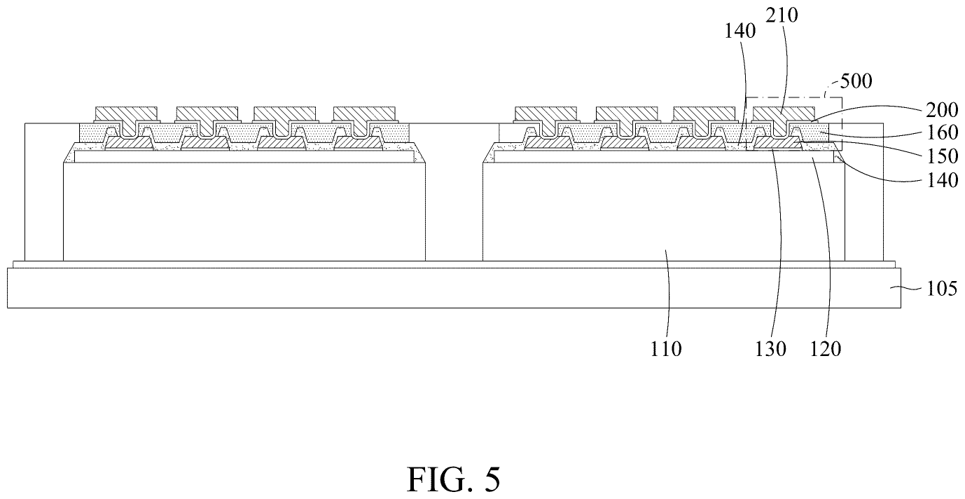

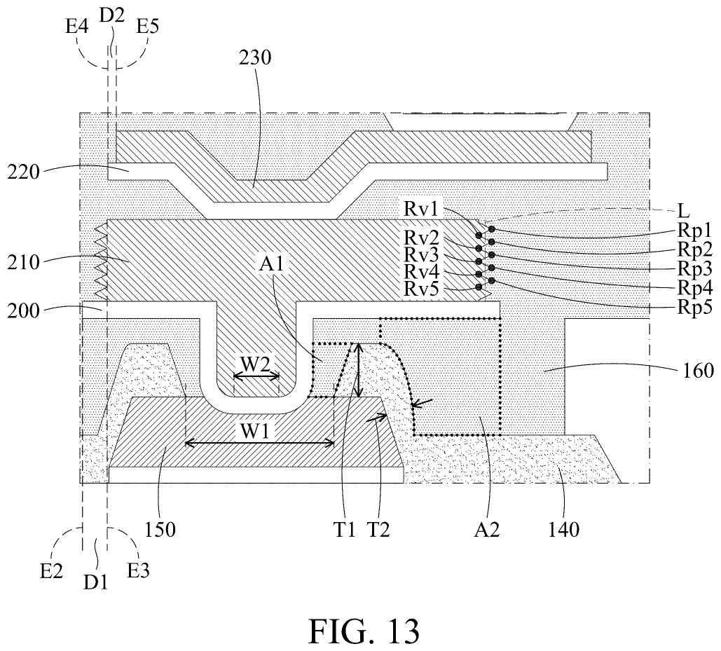

Referring to FIG. 5, the first seed layer 200 may be patterned through one or more lithography processes and/or etching processes. In addition, the side surface of the first conductive layer 210 may be roughened through an etching process, which may include a dry etching process, a wet etching process, or another suitable etching process. The roughening will be described in detail in FIG. 13 below. In other embodiments, after the formation of the dry film photoresists 190 (as shown in FIG. 3) and before the formation of the first conductive layer 210 (as shown in FIG. 4), the side surfaces of the dry film photoresists 190 may be roughened through an etching process such that the sidewall of the subsequently formed first conductive layer 210 may have a roughening effect due to the roughened side surfaces of the dry film photoresists 190.

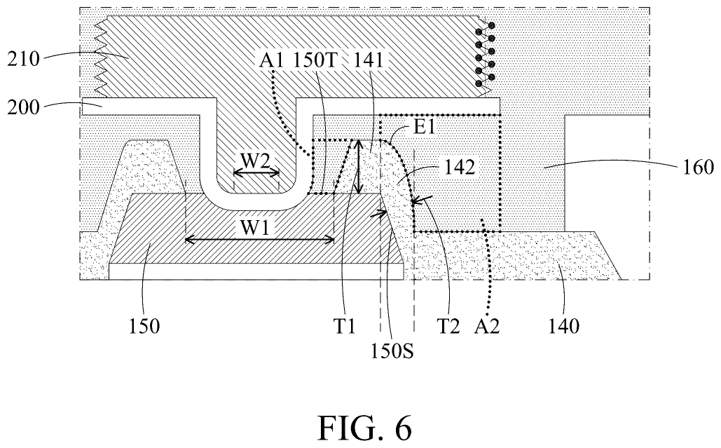

Referring to FIG. 6, FIG. 6 illustrates an enlarged view of a partial area 500 of the electronic device of FIG. 5. The lower half of the first conductive layer 210 contacting the conductive pad 150 has a curved edge, which can reduce the risk of peeling. In particular, if the lower half of the first conductive layer 210 contacting the conductive pad 150 is at a right angle, stress will be concentrated at the turning point of the right angle, resulting in an increased risk of peeling. In contrast, if the lower half of the first conductive layer 210 contacting the conductive pad 150 has the curved edge, stress will be changed and released in a radial manner along the curved edge without being concentrated in a single direction or a single turning point. Therefore, the risk of peeling can be reduced to improve the reliability of the electronic device.

Still referring to FIG. 6, the passivation layer 140 is disposed between the conductive pad 150 and the polymer layer 160, and the passivation layer 140 has an opening exposing the conductive pad 150. That is, the opening of the passivation layer 140 overlaps the conductive pad 150. In FIG. 6, the bottom width W2 of the first conductive layer 210 is smaller than the bottom width W1 of the opening. A ratio of the bottom width W2 to the bottom width W1 is within a range of 0.5 to 0.8 (greater than or equal to 0.5 and less than or equal to 0.8). That is, 0.5≤W2/W1≤0.8. The ratio of the bottom width W2 to the bottom width W1 within the above range can reduce the risk of peeling while maintaining a desired impedance. In particular, the bottom width W1 of the opening is the width of the conductive pad 150 exposed through the opening, and the bottom width W2 is the bottom-plane width of the first conductive layer 210 closest to the conductive pad 150. Since the material of the polymer layer 160 is more elastic than the passivation layer 140, the conductive pad 150 and the first conductive layer 210, it can have a buffering effect between the components. If the bottom width W2 of the first conductive layer 210 is too large, the space A1 will be compressed, and the amount of the polymer layer 160 that can be filled will be reduced, resulting in a decrease in the buffering capacity between the components. Therefore, the risk of peeling will be increased. If the bottom width W2 of the first conductive layer 210 is too small, the contact area between the first conductive layer 210 and the conductive pad 150 will be too small, resulting in an excessive impedance between the first conductive layer 210 and the conductive pad 150. Therefore, the ratio of the bottom width W2 to the bottom width W1 between 0.5 and 0.8 can reduce the risk of peeling while maintaining the desired impedance.

It should be understood that, in accordance with the embodiments of the present disclosure, a scanning electron microscope (SEM), an optical microscope (OM), a film thickness profiler (α-step), an ellipsometer or another suitable method may be used to measure the width, thickness or height of each element, or spacing or distance between elements. Specifically, in accordance with some embodiments, a scanning electron microscope may be used to obtain a cross-sectional image including the elements to be measured, and the width, thickness or height of each element, or spacing or distance between elements in the image can be measured.

Still referring to FIG. 6, the passivation layer 140 has a first portion disposed on the conductive pad 150. The first portion has a first segment 141 disposed on the top surface 150T of the conductive pad 150 and a second segment 142 disposed on the side surface 150S of the conductive pad 150. The first portion has a curved edge E1, which can reduce the risk of peeling and improve the reliability of the electronic device. In particular, if the edge E1 of the passivation layer 140 is linear, there will be a turning point between the side surface and the top surface of the passivation layer 140. Stress (for example, caused by differences in thermal expansion and contraction of the passivation layer 140 and the polymer layer 160) will be concentrated at the turning point, resulting in an increased risk of peeling. In contrast, if the edge E1 of the passivation layer 140 is curved, the stress will be changed and released in a radial manner along the curved edge E1 instead of being concentrated in a single direction or at the turning point. In addition, the curved edge E1 can increase the contact area with the polymer layer 160, thereby improving the adhesion between the passivation layer 140 and the polymer layer 160.

Still referring to FIG. 6, the first segment 141 of the passivation layer 140 has a thickness T1 on the top surface of the conductive pad 150 (measured along the normal direction of the top surface of the conductive pad 150), and the second segment 142 of the passivation layer 140 has a thickness T2 on the side surface of the conductive pad 150 (measured along the normal direction of the side surface of the conductive pad 150). The thickness T1 is greater than the thickness T2, which can reduce the risk of peeling and improve the reliability of the electronic device. In particular, since the material of the polymer layer 160 is more elastic than the passivation layer 140, the conductive pad 150 and the first conductive layer 210, it can have a buffering effect between the components. If the thickness T2 is greater than the thickness T1, the passivation layer 140 will compress the space A2, and the amount of the polymer layer 160 that can be filled will be reduced, resulting in a decrease in the buffering capacity between the components. Therefore, the risk of peeling will be increased. In contrast, if the thickness T1 is greater than the thickness T2, there will be more polymer layers 160 in the space A2, thereby having a better capacity for buffering the stress.

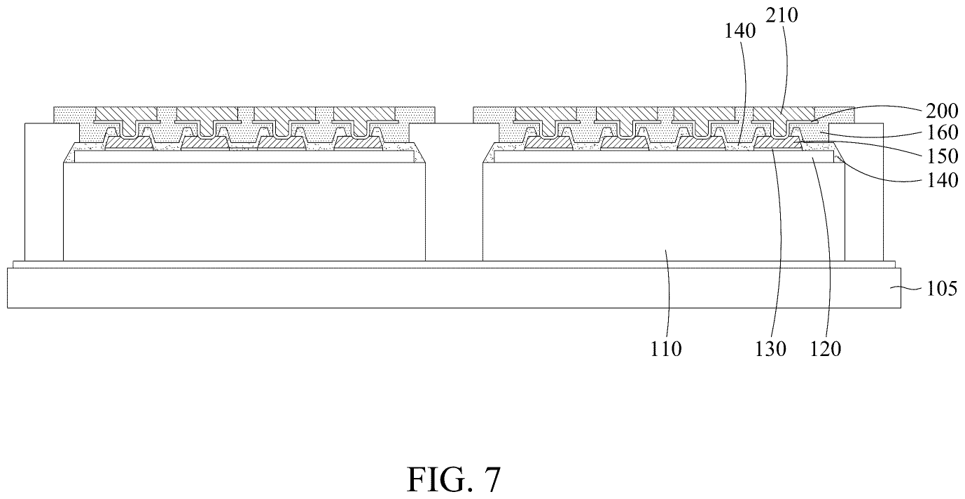

Referring to FIG. 7, the polymer layer 160 is formed on the first seed layer 200 and the first conductive layer 210, and a planarization process, such as a chemical mechanical polishing process, is performed to make the top surface of the polymer layer 160 flush with the top surface of the first conductive layer 210. The material and formation method of the polymer layer 160 can be deduced by reference to the description above. In the interests of brevity, the description thereof is not repeated herein.

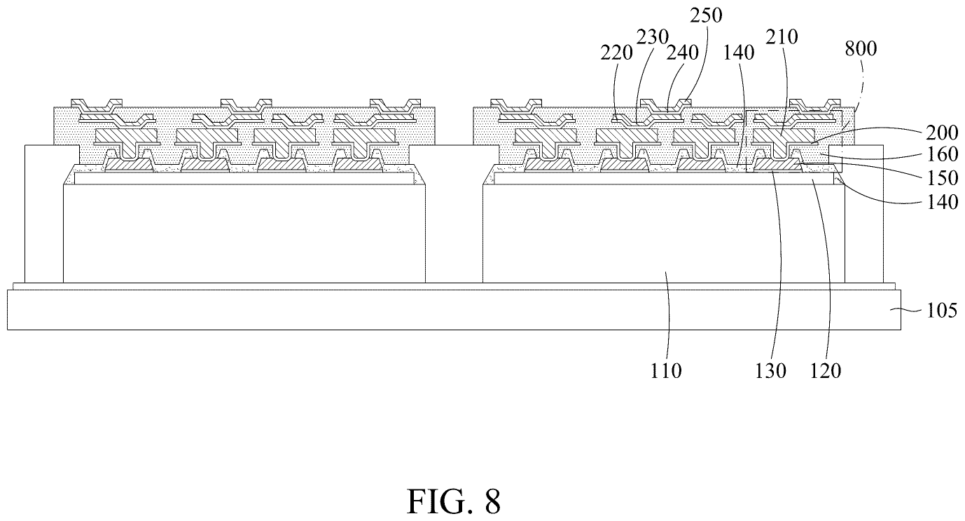

Referring to FIG. 8, a second seed layer 220, a second conductive layer 230, a third seed layer 240 and a third conductive layer 250 are formed on the first conductive layer 210. In some embodiments, the material and formation method of the second conductive layer 230 and the third conductive layer 250 may be similar to the material and formation method of the first conductive layer 210. In the interests of brevity, the description thereof is not repeated herein. The material and formation method of the second seed layer 220 and the third seed layer 240 may be similar to the material and formation method of the first seed layer 200. In the interests of brevity, the description thereof is not repeated herein.

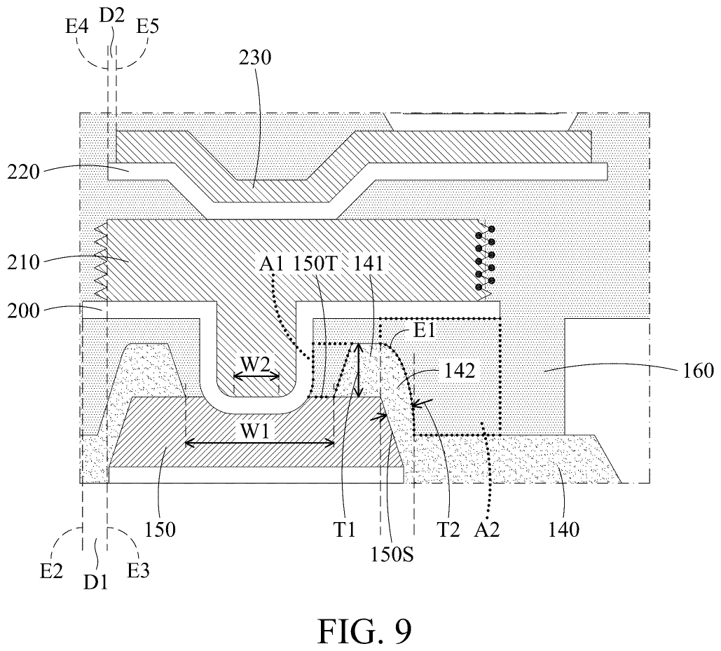

Referring to FIG. 9, FIG. 9 illustrates an enlarged view of a partial area 800 of the electronic device of FIG. 8. The first seed layer 200 is disposed between the conductive pad 150 and the first conductive layer 210. The side surface E2 of the first seed layer 200 protrudes from the side surface E3 of the first conductive layer 210 by a first distance D1. The first distance D1 is greater than zero, which can reduce the risk of peeling and improve the reliability of the electronic device. In particular, the adhesion between the first seed layer 200 and the polymer layer 160 is better than the adhesion between the first conductive layer 210 and the polymer layer 160. If the side surface of the first conductive layer 210 extends beyond the side surface of the first seed layer 200, or the two side surfaces are aligned, more portions of the first conductive layer 210 will directly contact the polymer layer 160. Due to poor adhesion between the first conductive layer 210 and the polymer layer 160, the risk of peeling will increase.

Still referring to FIG. 9, the second conductive layer 230 is disposed on the first conductive layer 210, and the second conductive layer 230 is electrically connected to the first conductive layer 210. The second seed layer 220 is disposed between the first conductive layer 210 and the second conductive layer 230. The side surface E4 of the second seed layer 220 protrudes from the side surface E5 of the second conductive layer 230 by a second distance D2. Since the first conductive layer 210 formed on the first seed layer 200 is thicker than the second conductive layer 230 formed on the second seed layer 220, the protruding distance of the side surface E2 of the first seed layer 200 from the side surface E3 of the first conductive layer 210 needs to be greater than the protruding distance of the side surface E4 of the second seed layer 220 from the side surface E5 of the second conductive layer 230 to ensure a secure attachment. That is, the first distance D1 is greater than the second distance D2, which can reduce the risk of peeling and improve the reliability of the electronic device.

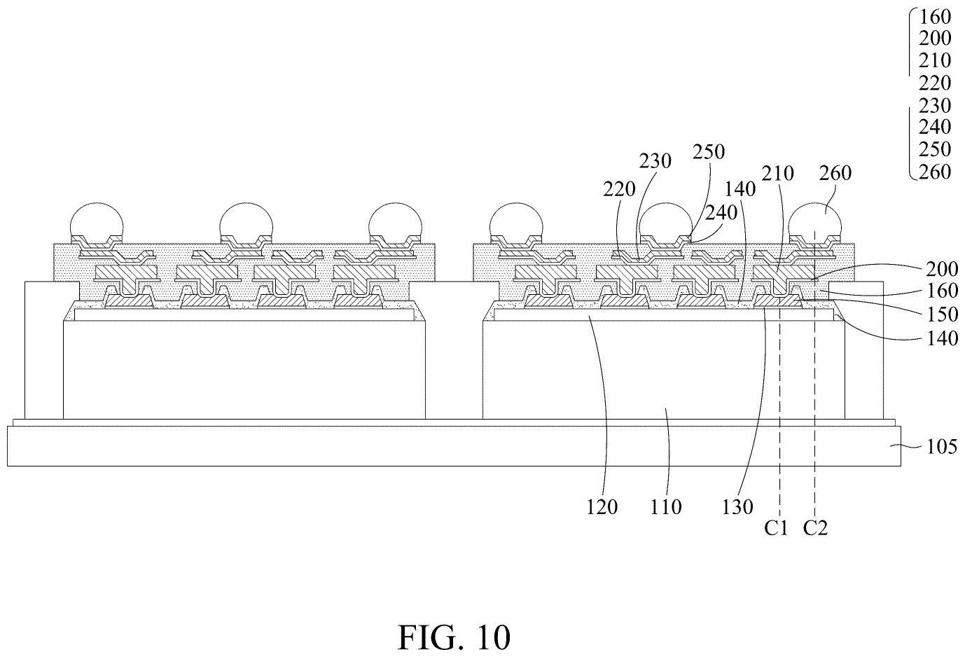

Referring to FIG. 10, bumps 260 are formed on the third conductive layer 250. In some embodiments, the bumps 260 may include copper (Cu), tin (Sn), bismuth (Bi), another suitable material, or a combination thereof, but the present disclosure is not limited thereto. In some embodiments, the bumps 260 may be formed on the third conductive layer 250 through a reflow process, a fusion bonding process, a metal-to-metal bonding process, another suitable method, or a combination thereof. As shown in FIG. 10, a redistribution structure 300 includes the first seed layer 200 and the first conductive layer 210 thereon; the second seed layer 220 and the second conductive layer 230 thereon; the third seed layer 240 and the third conductive layer 250 thereon; the polymer layer 160 surrounding the seed layer 200, 220, 240 and the conductive layers 210, 230, 250; and the bumps 260. As shown in FIG. 10, among the first conductive layer 210, the second conductive layer 230 and the third conductive layer 250, the first conductive layer 210 is closest to the conductive pad 150, and the center C1 of the conductive pad 150 is horizontally offset from the center C2 of one of the bumps 260.

It should be understood that the redistribution structure 300 may include any suitable number of polymer layers, seed layers, and conductive layers according to different embodiments. If needed, the steps and processes described above may be repeated to form more polymer layers, seed layers and conductive layers. The redistribution structure can redistribute the circuit of the electronic device and/or further increase the circuit fan-out area. Alternatively, different electronic components can be electrically connected to each other through the redistribution structure. Alternatively, the redistribution structure can redistribute a contact pad dimension for circuit fan-out or fan-in of a chip. For example, the distance between two adjacent contact pads of the redistribution structure contacting one end of the chip is smaller than the distance between two adjacent contact pads of the redistribution structure away from one end of the chip.

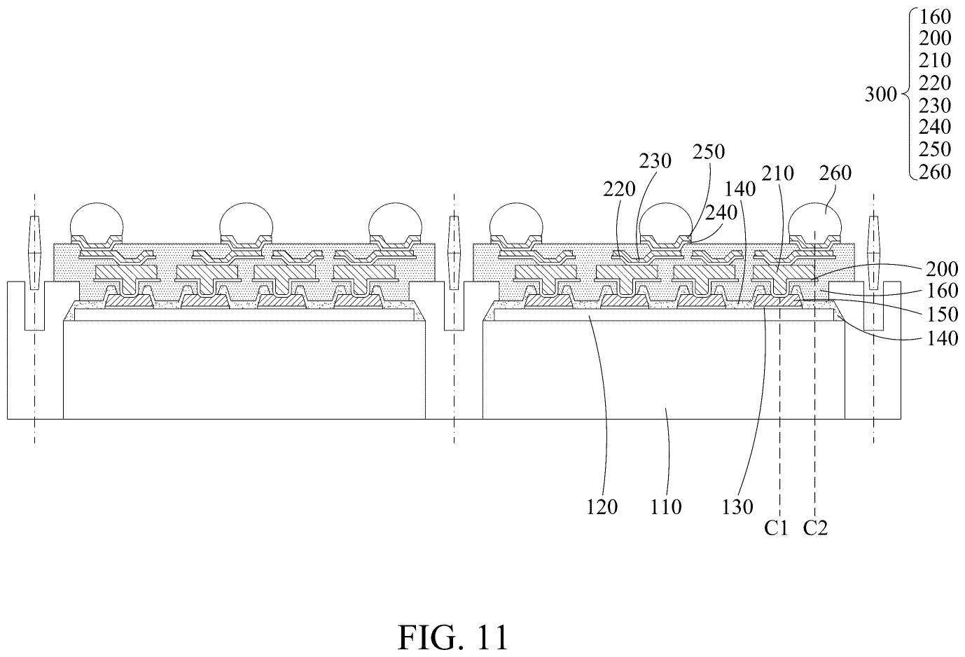

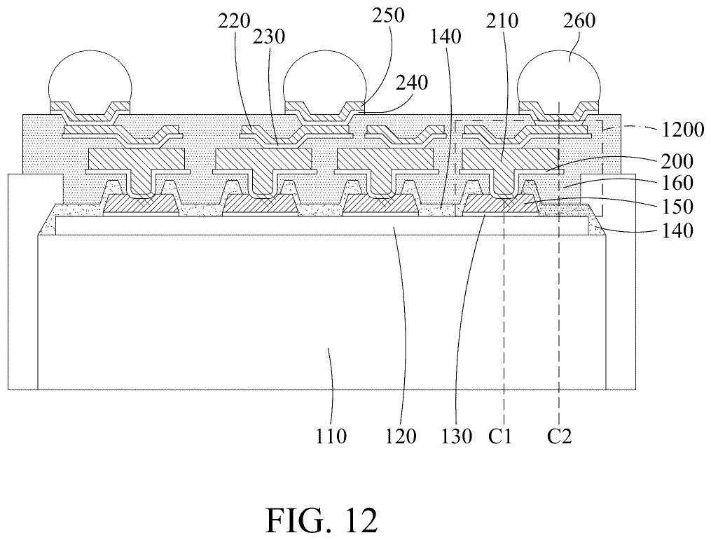

Referring to FIG. 11, an adhesive layer on the second substrate 105 may lose adhesion, for example, through a thermal process, an ultra-violet process or a laser process, so that the electronic component 110 and the structure thereon are separated from the second substrate 105. After being separated from the second substrate 105, a singulation process can be performed on the electronic component 110. The resulting structure is shown in FIG. 12.

Referring to FIG. 13, FIG. 13 illustrates an enlarged view of a partial area 1200 of the electronic device of FIG. 12. In some embodiments, after the formation of the first conductive layer 210, the side surface (side edge) of the first conductive layer 210 contacting the polymer layer 160 may be roughened through an etching process, and microstructures, such as a plurality of recesses, may be formed on the side edge of the first conductive layer 210. In some embodiments, the etching process may include a dry etching process, a wet etching process, or another suitable etching process. In some embodiments, the side edge of the first conductive layer 210 has a roughness Rz of 0.08 μm to 0.8 μm, which can reduce the risk of peeling to improve the reliability of the electronic device. In particular, if the side surface of the first conductive layer 210 is not roughened, the side surface of the first conductive layer 210 will be smooth and have a small contact area with the polymer layer 160, so that the first conductive layer 210 will easily peel off from the polymer layer 160. It should be noted that the roughness Rz described in the embodiments of the present disclosure is calculated from a cross-sectional view obtained through scanning electron microscope (SEM). In particular, in FIG. 13, five peak points Rp1, Rp2, Rp3, Rp4 and Rp5 are taken on the side edge of the first conductive layer 210, and five valley points Rv1, Rv2, Rv3, Rv4 and Rv5 are taken on the side edge of the first conductive layer 210. A reference line L is set between the peak points Rp1−Rp5 and the valley points Rv1-Rv5. Taking the value of the reference line L as 0, a side toward the peak points Rp1−Rp5 has a positive value, and a side toward the valley points Rv1−Rv5 has a negative value. The numerical difference between the peak point Rp1 and the valley point Rv1, the numerical difference between the peak point Rp2 and the valley point Rv2, the numerical difference between the peak point Rp3 and the valley point Rv3, the numerical difference between the peak point Rp4 and the valley point Rv4, and the numerical difference between the peak point Rp5 and the valley point Rv5 are calculated, respectively. The roughness Rz is the average value of the five sets of numerical differences above. Therefore, the roughness Rz can be expressed by the following formula:

$${R}_{z} = \frac{1}{5} {\sum }_{i = 1}^{5} {R}_{pi} - {R}_{vi}$$

It should be understood that for the purpose of clear illustration, FIG. 13 shows that the side surface of the first conductive layer 210 is roughened. However, the side surfaces of the second conductive layer 230 and the third conductive layer 250 formed subsequently may also be roughened.

To sum up, in some embodiments of the present disclosure, the side surface of the conductive layer is roughened so that the side surface of the conductive layer has a roughness Rz of 0.08 μm to 0.8 μm, thereby reducing the risk of peeling. In other embodiments of the present disclosure, by forming the contact portion between the conductive layer and the conductive pad into a curved shape and/or forming the edge of the passivation layer into a curved shape, stress can be prevented from being concentrated in a single direction or at a single turning point, so that the stress can be changed and released in a radial manner along the curved edge. Therefore, the risk of peeling is reduced. In addition, the ratio of the bottom width of the conductive layer to the bottom width of the corresponding opening is between 0.5 and 0.8. The space that the polymer layer can be filled increases without negatively affecting the impedance of the electronic device so that the buffering capacity is improved and the risk of peeling is reduced. Further, the thickness of the segment of the passivation layer on the side edge of the conductive pad is smaller than the thickness of the segment of the passivation layer on the top surface of the conductive pad. The space that the polymer layer can be filled increases so that the buffering capacity is improved and the risk of peeling is reduced. In some embodiments of the present disclosure, the side surface of the seed layer protrudes a distance from the side surface of the conductive layer, which can increase the area with better adhesion, thereby reducing the risk of peeling. In addition, the protrusion distance of the seed layer having the thicker conductive layer thereon is greater than the protrusion distance of the seed layer having the thinner conductive layer thereon to ensure a secure attachment.

Although some embodiments of the present disclosure and their advantages have been described in detail, it should be understood that various changes, substitutions and alterations can be made herein without departing from the spirit and scope of the present disclosure as defined by the appended claims. The features of the various embodiments can be used in any combination as long as they do not depart from the spirit and scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Thus, the appended claims are intended to include within their scope such processes, machines, manufacture, compositions of matter, means, methods or steps. Moreover, each claim constitutes an individual embodiment, and the claimed scope of the present disclosure includes the combinations of the claims and embodiments. The scope of protection of the present disclosure is subject to the definition of the scope of the appended claims. Any embodiment or claim of the present disclosure does not need to meet all the purposes, advantages, and features disclosed in the present disclosure.

What is claimed is:

1. An electronic device, comprising:
an electronic element;
a conductive pad disposed on the electronic element and electrically connected to the electronic element; and
a redistribution structure disposed on the conductive pad, wherein the redistribution structure comprises a plurality of conductive layers; a polymer layer enclosing the plurality of conductive layers; and a bump electrically connected to the conductive pad through the plurality of conductive layers;
wherein a center of the conductive pad is horizontally shifted from a center of the bump; and
wherein the plurality of conductive layers comprise a first conductive layer, the first conductive layer has a side surface contacting the polymer layer, and the side surface has a side edge having roughness of 0.08 μm to 0.8 μm in a cross-sectional view.

2. The electronic device of claim 1, wherein the first conductive layer of the plurality of conductive layers is closest to the conductive pad, and a lower portion of the first conductive layer has a curved edge in the cross-sectional view.

3. The electronic device of claim 1, further comprising a passivation layer disposed between the conductive pad and the polymer layer, wherein the passivation layer comprises an opening overlapping the conductive pad, and in the cross-sectional view, a first bottom width of the first conductive layer is less than a second bottom width of the opening.

4. The electronic device of claim 3, wherein the polymer layer fills a space between a lower portion of the first conductive layer and the passivation layer.

5. The electronic device of claim 3, wherein the first bottom width of the first conductive layer is a bottom-plane width of the first conductive layer closest to the conductive pad.

6. The electronic device of claim 3, wherein the second bottom width of the opening is a width of the conductive pad exposed through the opening.

7. The electronic device of claim 3, wherein a ratio of the first bottom width to the second bottom width is within a range of 0.5 to 0.8.

8. The electronic device of claim 3, wherein the passivation layer comprises a first portion disposed on the conductive pad, and the first portion comprises a first segment disposed on a top surface of the conductive pad; and a second segment disposed on a side surface of the conductive pad.

9. The electronic device of claim 8, wherein a thickness of the first segment is greater than a thickness of the second segment.

10. The electronic device of claim 9, wherein the thickness of the first segment is a thickness measured along a normal direction of the top surface of the conductive pad.

11. The electronic device of claim 9, wherein the thickness of the second segment is a thickness measured along a normal direction of the side surface of the conductive pad.

12. The electronic device of claim 8, wherein the first portion has a curved edge in the cross-sectional view.

13. The electronic device of claim 1, further comprising a first seed layer disposed between the conductive pad and the first conductive layer, wherein the first seed layer protrudes from the side surface of the first conductive layer by a first distance, wherein the first distance is greater than zero.

14. The electronic device of claim 13, wherein the plurality of conductive layers comprise a second conductive layer disposed on the first conductive layer, and the second conductive layer is electrically connected to the first conductive layer.

15. The electronic device of claim 14, further comprising a second seed layer disposed between the first conductive layer and the second conductive layer, wherein the second seed layer protrudes from a side surface of the second conductive layer by a second distance, and the first distance is greater than the second distance.

16. The electronic device of claim 14, wherein a thickness of the first conductive layer is greater than a thickness of the second conductive layer.

17. The electronic device of claim 14, wherein the second conductive layer has a roughened side surface.

18. The electronic device of claim 1, further comprising a molding layer sealing the electronic element.

19. The electronic device of claim 1, wherein the electronic element is a semiconductor die.

20. The electronic device of claim 1, wherein the electronic device is a semiconductor package.
